(19) United States
(12) Patent Application Publication
(10) Pub. No.: US 2004/0168636 A1
(43) Pub. Date: Sep. 2, 2004

(54) Process and apparatus for producing cystalline thin film buffer layers and structures having biaxial texture

(76) Inventors: Nicholas Savvides, NSW (AU); Sabaratnasingam Gnanarajan, NSW (AU); Alex Katsaros, NSW (AU)

Correspondence Address: KENYON & KENYON, 1500 K STREET, N.W., SUITE 700, WASHINGTON, DC, 20005, US

(21) Appl. No.: 10/478,181

(22) PCT Filed: May 22, 2002
(86) PCT No.: PCT/AU02/00641

(30) Foreign Application Priority Data
May 22, 2001 (AU) PR 5153

(51) Int. Cl. C23C 16/00; C23C 14/30

(52) U.S. Cl. 118/723 CB; 427/255.28; 427/248.1; 427/596

(57) ABSTRACT

The invention provides a method of depositing a buffer layer or film onto a surface of a substrate. The method includes providing the substrate in a controlled atmosphere and exposing the substrate to a vapour comprising a film forming species. While the substrate is exposed to the vapour, two or more ion beams are provided incident upon the surface of the substrate to assist formation of the film. The respective axes of incidence of the two or more ion beams are distinct and are selected and controlled in order to maintain the arrival rate ratio, maximise the deposition rate, and maximise the biaxial alignment of the layer so formed.

### FIELD OF THE INVENTION

The present invention relates to a method and apparatus for coating a substrate with a biaxially textured thin film buffer layer or layers and articles made thereon, and more specifically to such buffer layers and structures deposited on a substrate to form an article.

### DESCRIPTION OF THE PRIOR ART

There has been intense effort since the discovery of high temperature superconductors (HTS) to develop processes and apparatus to produce well oriented superconducting filaments supported by or embedded into metallic materials for purposes such as construction of large-scale electrical power devices such as transmission cables and transformers, windings for electric motors, coils for magnets and electrical power storage devices. A parallel effort has concentrated on developing HTS thin films and structures for applications in electronics such as use in magnetic field sensors, and applications in wireless telecommunications including microwave filters and high-Q oscillators.

Such applications typically demand that the superconductor when cooled below its transition temperature is able to handle very high critical current density, J_{c}, in magnetic fields ranging from zero to several Tesla.

It has been demonstrated by numerous reports in the scientific literature that HTS materials possess high J_{c} only when fabricated as single crystals or in essentially single crystal form as epitaxial thin films on single crystal substrates such as MgO, SrTiO₃, or LaAl₂O₃. Under these conditions the grains or crystallites from which the epitaxial film or filament is composed are bonded to each other such that their crystallographic directions are well aligned. In general, x-ray diffraction is used to characterise the degree of texture or alignment and it is accepted that a phi-scan full-width at half-maximum (FWHM) or Δφ of no more than 20° is required for high J_{c}. To achieve very high J_{c} it is customary to use single crystal substrates whose crystal structure bears a close relationship to that of the HTS. Particularly useful single crystal substrates are materials with a cubic structure such as MgO and yttria-stabilised zirconia (YSZ) or materials such as SrTiO₃ and LaAl₂O₃ whose structure closely relates to the perovskite structure of the HTS compounds such as YBa₂Cu₃O₇ (abbreviated as YBCO) and Bi_{1.6}Pb_{0.4}Sr₂Ca₂Cu₃O₁₀ (abbreviated as BSCCO). These single crystal substrates, however, are expensive and can not be produced in large areas or commercial lengths, and do not possess the mechanical flexibility and strength needed to scale up the technology for commercial electric power applications.

These limitations have been partly overcome by depositing a thin film buffer layer onto inexpensive metallic substrates such as Ni-alloy (eg. Hastelloy) and silver. The buffer layer typically consists of one or more ceramic oxide layers such as MgO, yttria-stabilised zirconia (YSZ), and cerium oxide (CeO₂). Because the processing of the HTS material is carried out at high temperatures, typically 600-900° C., one of the properties of the buffer layer is to act as a diffusion barrier to prevent metal species diffusing into the superconductor. The other important property of the buffer layer is that it must have a crystallographic texture as close as possible to a single crystal to allow the HTS material to grow epitaxially in order to possess the desired high J_{c}.

The HTS compound YBCO (and other compounds of similar composition and structure) is an important superconducting material for the development of high-J_{c} electrical conductors and thin film microwave devices. High J_{c}'s have been reported for polycrystalline YBCO thin films deposited onto metallic substrates onto which a biaxially textured non-superconducting oxide buffer layer is first deposited using a plasma process commonly known as ion-beam assisted deposition (IBAD).

As can be seen from the articles by lijima et al [J. Appl. Phys. Vol.74 (1993), pp. 1905-11; J. Mater. Res. Vol. 12 (1997), pp. 2913-23; J. Mater. Res. Vol. 13 (1998), pp. 3106-13] and Japanese patents JP6145977 (1994) and JP7105764 (1995), the biaxial growth of a thin film occurs due to the action of an energetic ion beam provided by an ion beam source which bombards the growing film during deposition. These methods make use of a Kaufman type ion beam source or gun to bombard the film with a beam of Ar+ or Kr+ ions. The IBAD process has been confirmed by many researchers including the present inventors [Appl. Phys. Lett. Vol.70 (1997), pp. 2816-18; EUCAS'99 Conf., Sitges, Spain, 14-17 Sep. 1999].

All variants of the IBAD method use a single ion-beam source to bombard the growing film with energetic ions, usually, Ar+ ions, of energy typically in the range 100-500 eV; the ion beam current is typically in the range 50 to 200 μA/cm². The degree of biaxial alignment of the buffer is greatest when the direction of the ion beam is 50°-60° to the normal of the substrate surface. Also of importance is the so called arrival rate ratio which is the ratio of the number of energetic ions (from the ion beam) arriving at the growing film to the number of the atomic species that condense on the substrate to form the film. As the energetic ion beam bombards the growing film it causes significant re-sputtering so that the effective deposition rate is greatly diminished compared to the situation where ion bombardment is absent. This re-sputtering problem and the need to operate within a narrow window of arrival rate ratio place a limit on the effective rate at which biaxial buffer layers are produced.

A further limitation of the IBAD method is that very thick buffer layers (thicker than 500 nm) are required to achieve an acceptable degree of biaxial alignment. For example, lijima et al [J. Mater. Res. Vol.13 (1998), pp. 3106-13] reported that YSZ buffer layers needed to be more than 800 nm thick to achieve FWHM of 20°. Similarly, Freyhardt et al [IEEE Trans. Appl. Supercon. Vol.7 (1997), pp.1426-31] reported that to achieve FWHM of 15° or less the YSZ buffer layers must be at least 500 nm thick while layers 1500 nm thick are needed to achieve 10° FWHM.

Several techniques based on IBAD have been described in the scientific and patent literature for the deposition of biaxially aligned crystalline oxide buffer layers. The buffer layer is typically deposited onto a technical substrate such as a Ni-alloy (eg. Hastelloy) or sapphire wafer. If desired, an additional layer or layers are deposited to form a multilayer thin film structure. The function of the oxide buffer is to act as a diffusion barrier and/or a template to promote the epitaxial growth of a highly textured or biaxially aligned film that is subsequently deposited upon it.

In particular, the IBAD process has been used to deposit cubic oxide buffer layers (eg. YSZ, CeO₂) onto Hastelloy tape which is subsequently coated with a superconducting film such as YBa₂Cu₃O₇ to form what is known as YBCO coated conductor or YBCO tape. Necessary conditions to achieve the best quality YBCO tape are that the crystal structure of the buffer layer is closely matched to that of the YBa₂CU₃O₇ material and that the buffer layer has a high degree of biaxial alignment or texture. In general, the degree of biaxial alignment is assessed by measuring the Full-Width at Half-Maximum (FWHM) or Δφ using x-ray diffraction φ-scans. Other applications include deposition of CeO₂ onto large area sapphire (Al₂O₃) wafers that are subsequently coated with YBCO film and used for power applications such as fault current limiters and microwave components such as filters operating in the GHz range.

In a process described in U.S. Pat. No. 5,898,020 (Goyal et al), biaxial alignment is imparted to a metal tape (made of Ni or Ni-alloy or silver) by rolling and heat treatment. The metal tape so produced is called RABiTS (Roll-Assisted Biaxial Texture Substrate). Since the metal tape is biaxially aligned it acts as the template for the epitaxial growth of buffer layers (YSZ, CeO₂) which are deposited without ion assistance using laser ablation or magnetron sputtering or evaporation.

Biaxial buffer layers are also used as gas sensing electronic ceramic elements, as templates for the growth of electro-ceramic films such as ferroelectric films, as dielectric insulators in semiconductor devices, and to form superconductor/ferroelectric and superconductor/ferromagnetic heterostructures.

Texture refers to the alignment of grains or crystallites in a preferred direction as can be determined by x-ray diffraction techniques. For example, a polycrystalline thin film such as CeO₂ which has a cubic crystal lattice is said to be textured or biaxially aligned if all the crystallites or grains are oriented such that they all have the c-axis normal to the film plane and the a-b axes oriented in the plane. Such texture is also known as cube texture. In practice, textured materials contain a large number of crystallites that are not perfectly aligned either in the c-axis or the a-b axes. Provided the misalignment is such that the FWHM measured from phi scans (or φ-scans) is less than 20° the material is said to be biaxially aligned. The magnitude of the FWHM or Δφ is used as a measure of the degree of texture or biaxial alignment, ie. the degree of biaxial alignment increases as the FWHM decreases. By contrast, a single crystal has perfect biaxial alignment and hence the FWHM is typically 0.1°.

Any discussion of documents, acts, materials, devices, articles or the like which has been included in the present specification is solely for the purpose of providing a context for the present invention. It is not to be taken as an admission that any or all of these matters form part of the prior art base or were common general knowledge in the field relevant to the present invention as it existed before the priority date of each claim of this application.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY OF THE INVENTION

According to a first aspect, the present invention provides a method of depositing a film onto a surface of a substrate, comprising the steps of:

providing the substrate in a controlled atmosphere;

exposing the substrate to a vapour comprising a film forming species; and

while the substrate is exposed to the vapour, providing at least first and second ion beams incident towards the surface of the substrate to assist formation of the film, wherein an axis of incidence of the first ion beam relative to the surface of the substrate is distinct from an axis of incidence of the second ion beam relative to the surface of the substrate.

It has been realised that by providing two or more ion beam sources, a higher deposition rate can be achieved while maintaining an optimum arrival rate ratio. Further, it has been found that the use of two or more ion beams in ion assisted deposition provides a thin film of given thickness with a higher degree of biaxial alignment than such a film formed by known ion beam assisted deposition techniques.

Preferably, the axis of incidence of the first ion beam and the axis of incidence of the second ion beam are symmetrically disposed about the normal of the surface of the substrate.

Preferably, the first and second ion beams are incident at an angle in the range of 50-60 degrees from the normal of the surface of the substrate. More preferably, the first and second ion beams are incident at an angle of 55 degrees from the normal of the surface of the substrate.

The ion beams preferably comprise ions of a noble gas, such as Ar, Kr or Xe. Typically, the ion beam will also comprise some small amount of oxygen.

The step of providing first and second ion beams may comprise simultaneously providing the first and second ion beams, or alternatively may comprise sequentially providing the first and second ion beams.

The method of the first aspect of the present invention may further comprise providing third, fourth or additional ion beams. In such embodiments, the axes of incidence of the ion beams are preferably symmetrically disposed about the normal of the surface of the substrate. For instance, where three ion beams are provided, the axes of incidence of the ion beams are preferably disposed at an angle of 55 degrees to the normal of the surface of the substrate and are preferably situated at 120 degree intervals about the normal of the surface of the substrate, or, where four ion beams are provided, the axes of incidence of the ion beams are preferably disposed at an angle of 55 degrees to the normal of the surface of the substrate and are preferably situated at 90 degree intervals around the normal of the surface of the substrate.

The method of the present invention may comprise the subsequent step of forming a superconducting article by depositing an epitaxial superconducting material over the film. The superconducting material may be deposited by any manner of techniques such as magnetron deposition, laser ablation, or chemical vapour deposition. Such embodiments of the invention enable formation of a superconducting article with a superior FWHM, for instance having an x-ray phi scan peak of not more than 20 degrees FWHM.

Such embodiments of the invention may further comprise an additional subsequent step of forming a capping layer over the epitaxial superconducting material. Such a capping layer may serve as a stabilising layer, and/or offer mechanical or environmental protection or act as an electrical shunt.

The method of the first aspect of the present invention may comprise the additional step of negatively electrically biasing the substrate during formation of the film. Negative biasing the substrate can enhance biaxial alignment of the film being formed.

The method of the first aspect of the invention is applicable to a wide range of substrates, and may be used in the formation of a buffer layer or multi layer structures onto crystalline or amorphous substrates such as a single crystal, metallic, alloy, semiconductor or ceramic substrate. Further, the buffer layer may be formed on such a substrate in a variety of geometries, such as sheet, disc, wire rod, tube and tape. Additionally, the invention enables fabrication of biaxially aligned oxide buffer layers on an elongated substrate such as a wire or tape for the manufacture of coated superconductors. The final article thus produced may further comprise ferroelectric, ferromagnetic or optoelectronic devices epitaxially joined to the substrate. The final article could, for example, be an electrical sensor such as a gas sensor. The method of the present invention may also be used in depositing c-axis oriented, biaxially textured perovskite-like electro-ceramic films such as ferroelectrics.

According to a second aspect, the present invention provides an apparatus for depositing a film onto a surface of a substrate, the apparatus comprising:

a chamber to control the atmosphere in which the substrate is situated;

a vapour source to provide a vapour comprising a film forming species to the surface of the substrate; and

at least first and second ion beam sources operable to provide at least first and second ion beams incident towards the surface of the substrate to assist formation of the film, wherein an axis of incidence of the first ion beam relative to the surface of the substrate is distinct from an axis of incidence of the second ion beam relative to the surface of the substrate.

The ion beam sources are preferably operable to provide ion beams either sequentially or simultaneously. The first and second ion beam sources may be any suitable apparatus such as Kaufman ion guns capable of providing a collimated source of energetic ions.

The vapour source providing the deposited species may be implemented by any suitable apparatus, such as a magnetron sputter source capable of providing a physical vapour of atoms or molecules.

Embodiments of this invention enable the formation of a film or buffer layer with a thickness from 200 nm to 500 nm or thicker with a high degree of biaxial alignment (Δφ<20°), the films having dense microstructure and free of large voids and cracks. Further, the rate of deposition of the present invention can be significantly greater than the rate obtained when using prior art ion beam assisted deposition techniques. The biaxial alignment of a buffer layer deposited in accordance with the present invention, measured by x-ray techniques, can be significantly improved from that of a buffer layer of the same composition deposited under similar conditions but using prior art deposition techniques. Additionally, sequential ion beam bombardment using the present invention can enhance the crystalline quality in the c-axis direction (ie. improves FWHM of omega scans) and can minimise the out-of-plane or c-axis tilt of crystallites, and the biaxial alignment of buffer layers may be further enhanced by applying a negative bias to the substrate.

### BRIEF DESCRIPTION OF THE DRAWINGS

Examples of the invention will now be described with reference to the accompanying drawings in which:

FIGS. 1a and 1b are schematic views of substrates having coated layers in accordance with embodiments of the invention;

FIGS. 2a and 2b illustrate the concept of alignment or texture in a crystalline film;

FIG. 3 illustrates an apparatus in accordance with an embodiment of the present invention for depositing biaxial buffer layers onto substrates;

FIG. 4 illustrates an arrangement of an apparatus of another embodiment in accordance with the present invention for depositing biaxial buffer layers onto substrates;

FIG. 5 illustrates a method of the present invention for depositing a biaxial buffer layer onto a moving elongated substrate such as a wire or tape;

FIG. 6 illustrates a tandem arrangement in accordance with a further embodiment of the present invention for depositing biaxial buffer layers onto moving elongated substrates;

FIGS. 7a and 7b show YSZ(111) x-ray phi scans and pole figures comparing the texture of YSZ films deposited by prior art techniques and by an embodiment of the invention onto Hastelloy substrates;

FIGS. 8a and 8b show CeO₂(111) x-ray phi scans and pole figures comparing the texture of CeO₂ films deposited by prior art techniques and by an embodiment of the present invention onto Hastelloy substrates;

FIGS. 9a to 9d show YSZ(111) x-ray phi scans and pole Figures of YSZ buffer layers, showing the effect on texture by increasing an ion beam energy;

FIG. 10 shows YSZ(111) x-ray phi scans and pole Figures of YSZ buffer layer deposited onto Hastelloy substrate using a further embodiment of the method of the present invention;

FIG. 11 shows YSZ(111) x-ray phi scans of YSZ buffer layers deposited onto Hastelloy substrates using a further embodiment of the method of the present invention, and showing the evolution of texture with increasing layer thickness;

FIGS. 12a and 12b show x-ray diffraction of CeO₂ films deposited at room temperature onto single crystal YSZ(100) substrates, showing the absence of texture when the film is produced without ion-beam assistance and c-axis texture when the film is produced by an embodiment of the method of the present invention;

FIG. 13 shows the YSZ(111) phi scan of a YSZ buffer layer deposited onto a crystalline silicon substrate by an embodiment of the method of the present invention, showing a very high degree of biaxial alignment;

FIGS. 14a and 14b show YBCO (103) x-ray phi scans and pole figures of two YBCO tapes fabricated by depositing YBCO film onto YSZ/Hastelloy substrates deposited in accordance with the present invention;

FIG. 15 shows YBCO(103) x-ray phi scan of a YBCO film deposited onto a YSZ/Si substrate deposited in accordance with the present invention and showing a high degree of epitaxial alignment of the YBCO film;

FIG. 16 shows the critical current density J_{c} (77K) of YBCO tapes as a function of Δφ of the YBCO(103) x-ray phi scan peak; and

FIG. 17 shows the critical current density J_{c} as a function of temperature for several high-Jc YBCO tapes.

### DETAILED DESCRIPTION OF THE PREFERRED EMBODIMENTS

It is to be understood that the acronym DIBAD when used below may refer to the use of two or more ion beams.

A biaxially textured buffer layer is deposited onto a substrate material. The substrate can be made from a crystalline material such as a metal or alloy, a semiconductor such as silicon, an oxide ceramic such as MgO or sapphire, or from a range of non-crystalline material such as glass. The substrate can be made from a partially or fully stabilised zirconia substrate, for example in very thin flexible sheet form, such as is provided under the name Ceraflex by MarkeTech International of 4750 Magnolia St, Port Townsend, Wash, 98368, USA. Once the substrate is coated with the textured buffer layer a second layer of a different material is deposited onto the buffer layer under suitable conditions so that a similar biaxial alignment is induced in the second layer. The process may be repeated to build up a structure consisting of one or more buffer layers and one or more epitaxial layers.

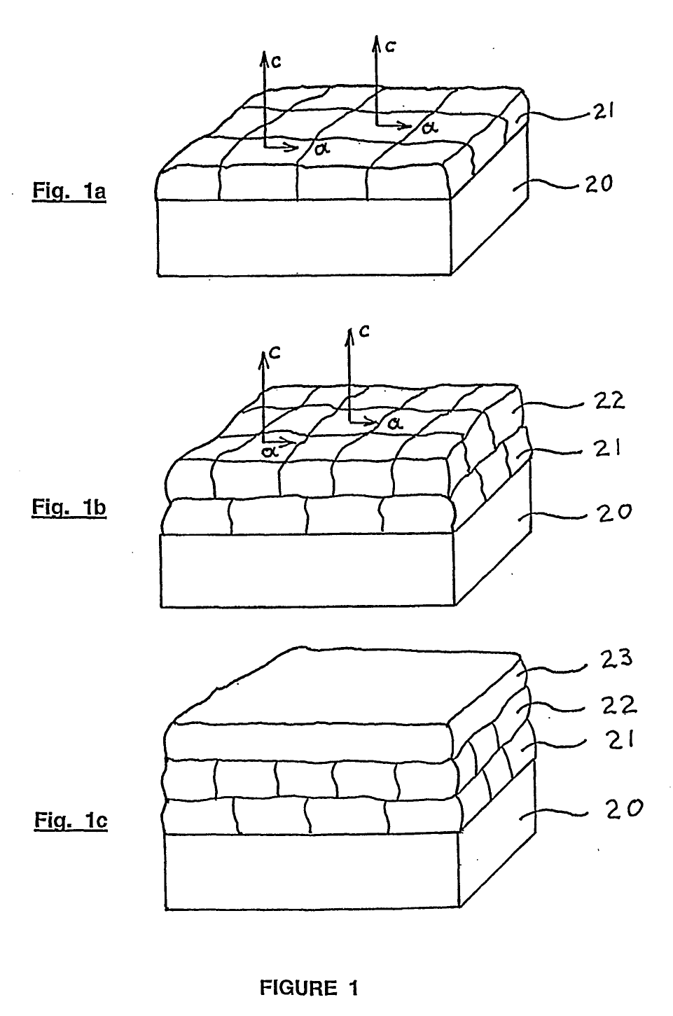

FIGS. 1a, 1b and 1c show schematic views of a substrate 20 coated with a biaxial layer 21 onto which an epitaxial layer 22 is induced to grow, followed by a capping layer 23. In addition, the buffer layer 21 may consist of several biaxial thin films each of different composition, and the structure so formed serves as the template for the subsequent growth of an epitaxial layer 22. For example, layer 22 may be an epitaxial YBa₂Cu₃O₇ thin film, forming a superconducting article. The capping layer 23 may be a coating for environmental protection or a highly conducting metal layer such as silver or gold to serve as an electrical shunt.

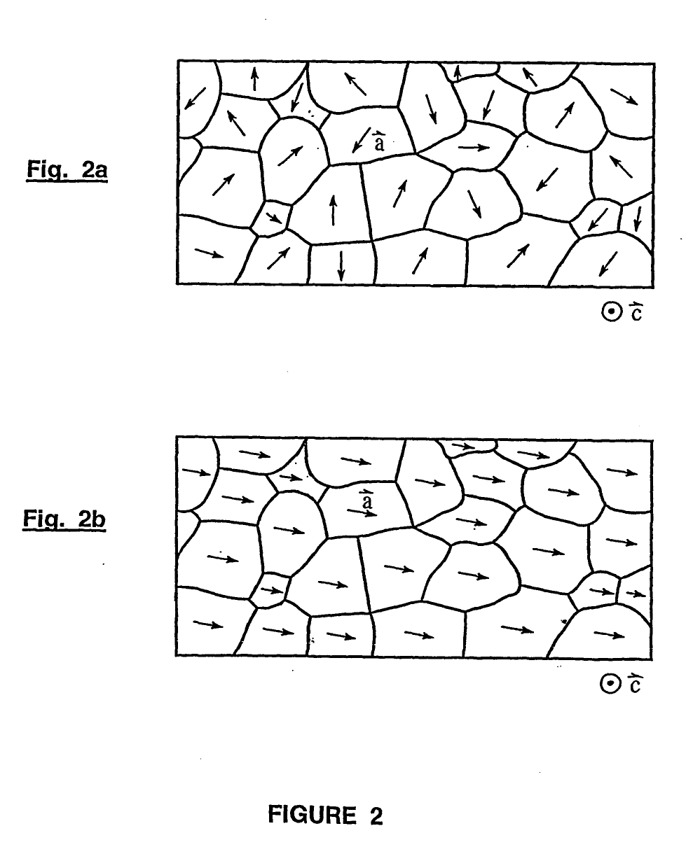

FIG. 2 shows a plan view of the concepts of c-axis alignment and biaxial alignment for a material with a cubic crystal structure. In FIG. 2(a) the grains or crystallites have their c-axis aligned normal to the -plane (ie. out-of-plane alignment) but are random in the a-b plane (uniaxial alignment). FIG. 2(b) shows perfect biaxial alignment where the crystallites are both c-axis and a-b axes aligned, ie. in-plane and out-of-plane aligned or cube textured.

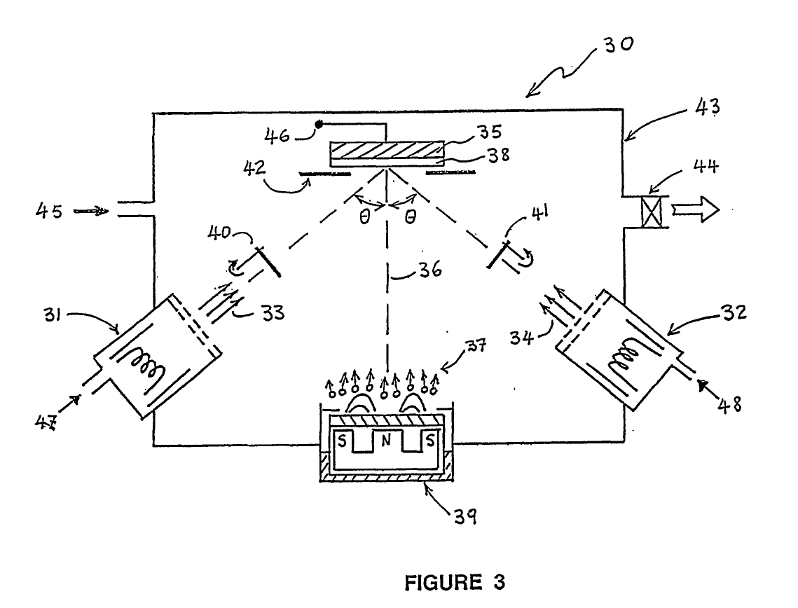

FIG. 3 shows a schematic illustration of a preferred embodiment of the invention employing the DIBAD method. Apparatus 30 consists of a vacuum chamber 43 evacuated with a vacuum pump via port 44, gas inlet 45, and with two ion beam sources (31 and 32) each having a gas inlet 47, 48 and arranged symmetrically opposite each other such that the ion beams 33 and 34 are directed towards the substrate 35 at an angle θ to the normal (36) of the substrate plane. Although the angle θ can vary from about 20° to 70° the preferred angle is between 50° and 60° with the ideal choice of 55°. In this embodiment of the invention the vapour of atoms 37 and such like which condense on the substrate 35 to form the film 38 are supplied by the target of a planar magnetron sputter source 39. The electrical power to the magnetron 39 is DC or low frequency AC or RF. Using available shutters 40, 41 the ion beams 33, 34 are caused to bombard the growing film 38 simultaneously or sequentially through aperture 42. The substrate is appropriately electrically biased via control 46.

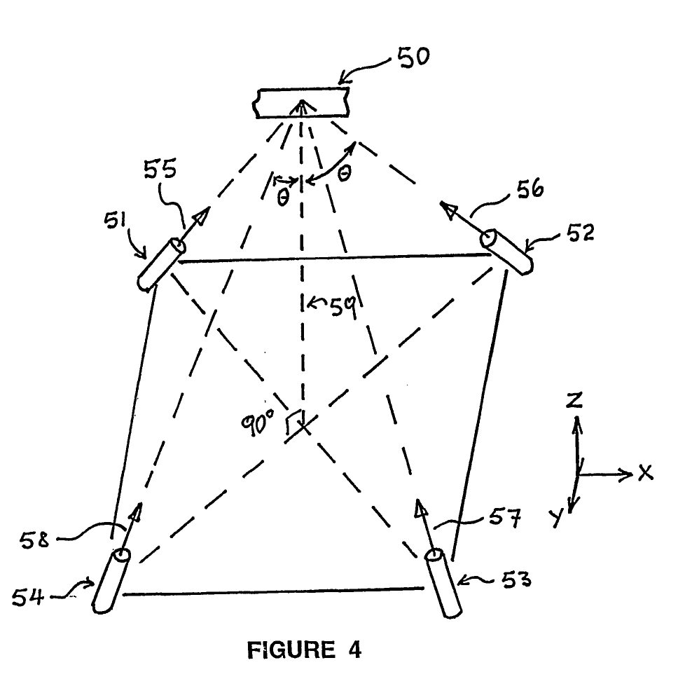

FIG. 4 is a schematic illustration of a Dual DIBAD method for depositing a biaxially aligned buffer layer onto a substrate 50. Four individual ion-beam sources (51-54) or guns are located at the comers of the base of a nominal pyramid and their ion beams (55-58) are directed towards the substrate 50 which is located at the apex of the nominal pyramid and situated in a plane parallel to the base of the nominal pyramid. Each directed ion beam (55-58) makes an angle θ with respect to the normal 59 of the film plane, where θ is 50-60° and preferably 55°. The distance of each ion gun 51-54 from the substrate 50 can be varied by moving the gun along the respective edge of the nominal pyramid. Coating a large-area substrate is achieved by translating the substrate in the X and/or Y direction. Coating a tape is achieved by moving the tape in the X direction. The advantages of the Dual DIBAD system are increased ion bombardment of the growing film and deposition rates up to four times that achieved by a single ion beam gun.

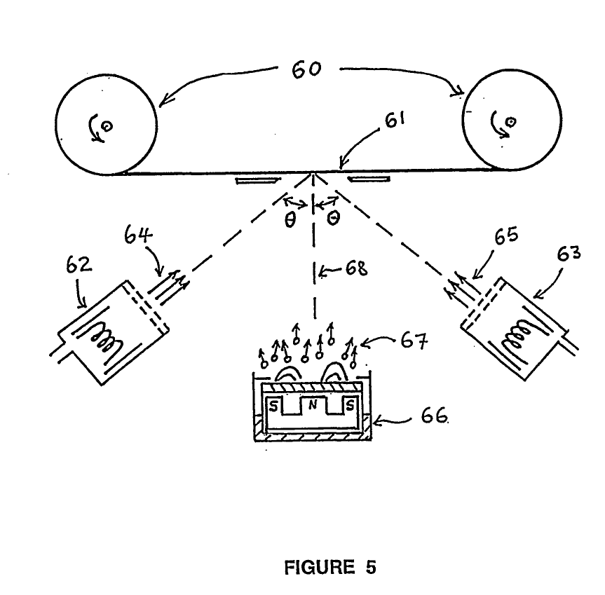

FIG. 5. shows an embodiment of the invention for use in coating elongated substrates such as metal tapes and wires. The illustration shows a spool-to-spool arrangement 60 for a single tape 61. As for the previous embodiments, ion beam sources 62, 63 generate ion beams 64, 65 incident to the tape at angle θ to the normal 68, and magnetron 66 generates vapour 67. Extensions of this arrangement consist of a number of spools feeding a number of individual lengths of tape in parallel to be coated simultaneously, or a pair of rollers over which a long piece of tape makes many passes such that parallel lengths of the tape are coated simultaneously.

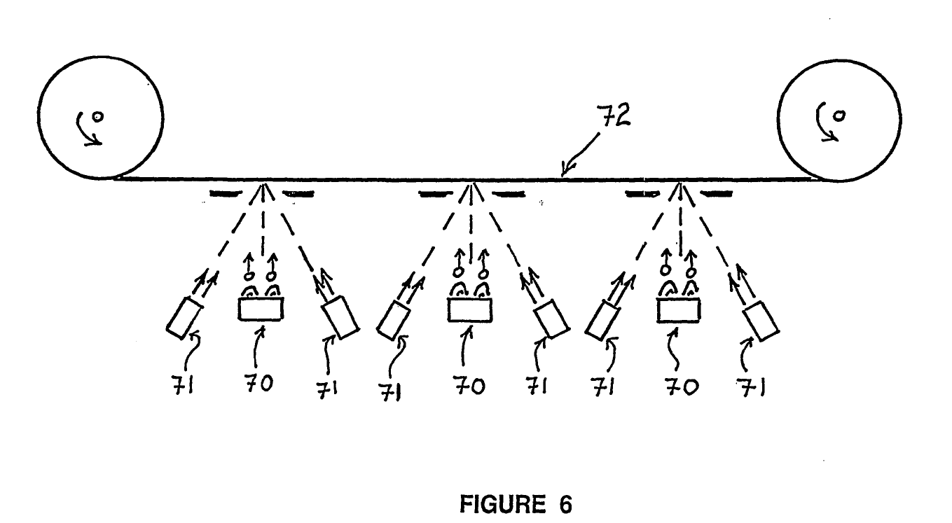

FIG. 6 shows a tandem arrangement of DIBAD using planar magnetron sputter sources 70 to provide the depositing species, and ion beam sources 71 to bombard the film on the tape 72 during formation. In other tandem arrangements the source of depositing species may be supplied by any manner of physical vapour sources such as laser ablation.

In these and other embodiments of the invention the vapour of atoms may be supplied by any other method capable of producing a physical vapour including cylindrical and post magnetrons, ion-beam sputtering, laser ablation, vacuum arc deposition, and electron-beam and thermal evaporation.

Formation of Biaxial Texture in the Buffer Layer by DIBAD

It has been realised that the development of texture is essentially the interplay between the energy of the bombarding ions and the ratio of the number of these ions to the number of the depositing atom species. These parameters are thus optimised to achieve the highest possible degree of biaxial texture and deposition rate. In the prior art, bombardment of a growing film by energetic ions during growth, as occurs in the IBAD process, causes significant re-sputtering of the film, ie. some material is sputtered off and hence lost Consequently, the deposition rate decreases compared to the rate that would be obtained in the absence of the ion beam bombardment.

By the use of two independent ion beams (DIBAD method) to achieve biaxial alignment, the number of ions that bombard the film can be increased and by doing so a corresponding increase in the supply of depositing vapour species can be realised. Consequently the deposition rate is increased by about two times while maintaining the same arrival rate ratio. In addition, the DIBAD method can enhance c-axis alignment and biaxial texture.

### EXAMPLE 1

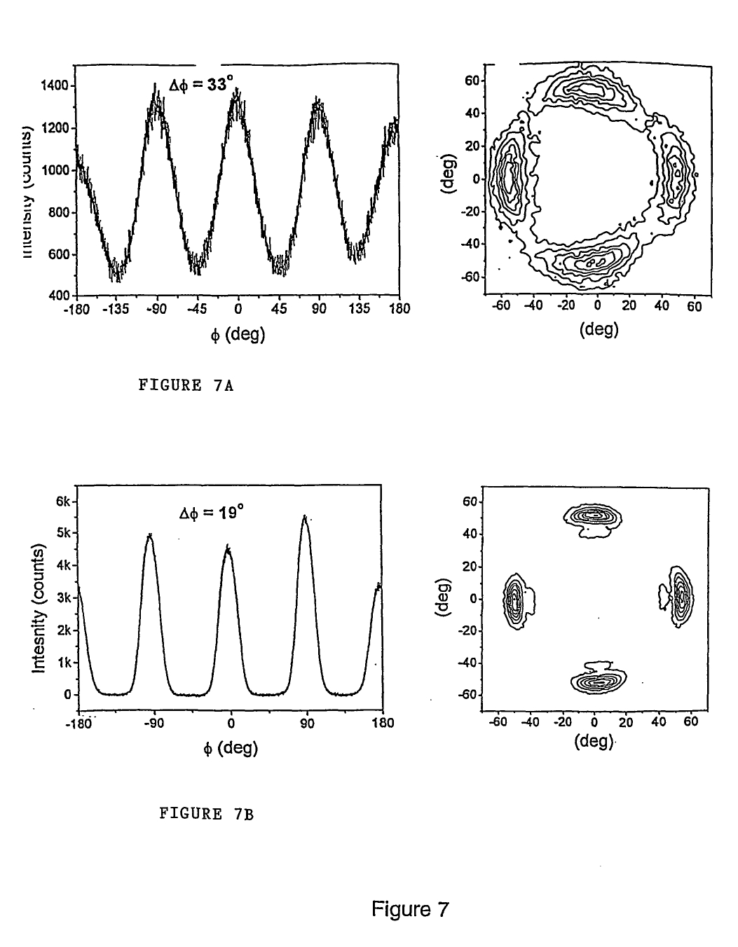

Biaxial YSZ buffer layers were deposited onto Hastelloy substrates by DIBAD and IBAD (prior art) to compare the degree of biaxial alignment. The individual layers were deposited under identical conditions as follows: Ar+ ions; angle of incidence θ=55°; ion beam energy=200 eV; ion to atom arrival rate ratio=0.05. FIG. 7 shows YSZ(111) x-ray pole figures and phi scans. FIG. 7a shows the results for a YSZ film deposited by IBAD, and FIG. 7b shows the results for a YSZ film deposited by DIBAD. The YSZ(111) x-ray phi scan peak of the layer deposited by the DIBAD technique has a FWHM or Δφ=19° while that deposited by IBAD has Δφ=33°. These results clearly demonstrate that under similar deposition conditions the DIBAD method yields buffer layers that have a sharper texture than those deposited by the IBAD method.

### EXAMPLE 2

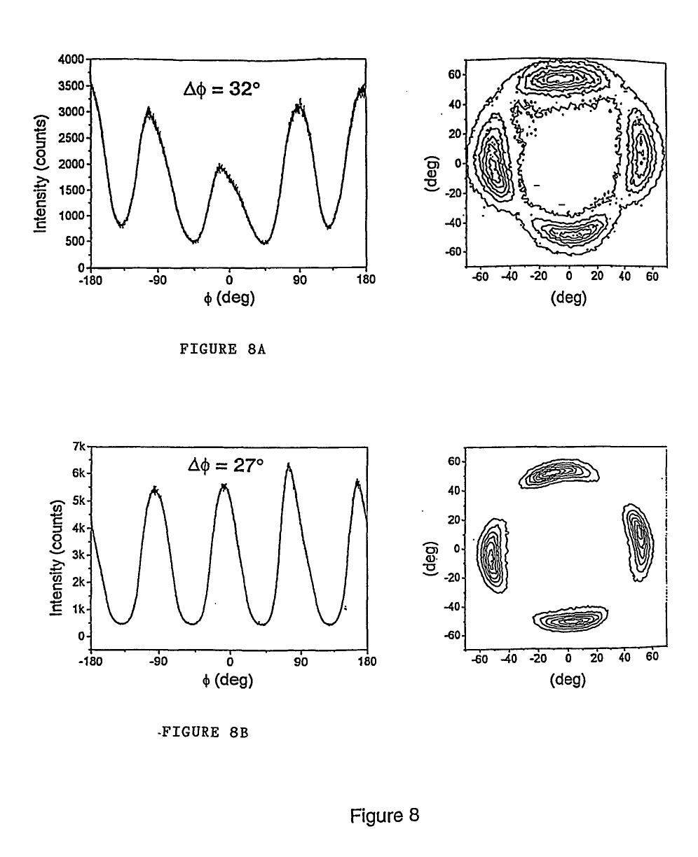

Biaxial CeO₂ buffer layers were deposited onto Hastelloy substrates by DIBAD and IBAD (prior art) to compare the degree of biaxial alignment. FIG. 8 shows CeO₂(111) x-ray pole figures and phi scans of the CeO₂ buffer layers, where FIG. 8a relates to the CeO₂ film deposited by IBAD, and FIG. 8b relates to the CeO₂ film deposited by DIBAD. The deposition conditions were: Ar+ ions; angle of incidence Δ=55°; ion beam energy=300 eV; ion to atom arrival rate ratio=0.05. The phi scan peak of the IBAD CeO₂ layer (FIG. 8a) yields Δφ=32° while that of the DIBAD CeO₂ layer (FIG. 8b) yields Δφ=27°. These results clearly demonstrate that the DIBAD technique yields the sharper biaxial texture. In addition, the phi scans and pole figures of the DIBAD film have a better circular symmetry indicating a lower tilt of the out-of-plane or c-axis orientation compared to the IBAD film.

### EXAMPLE 3

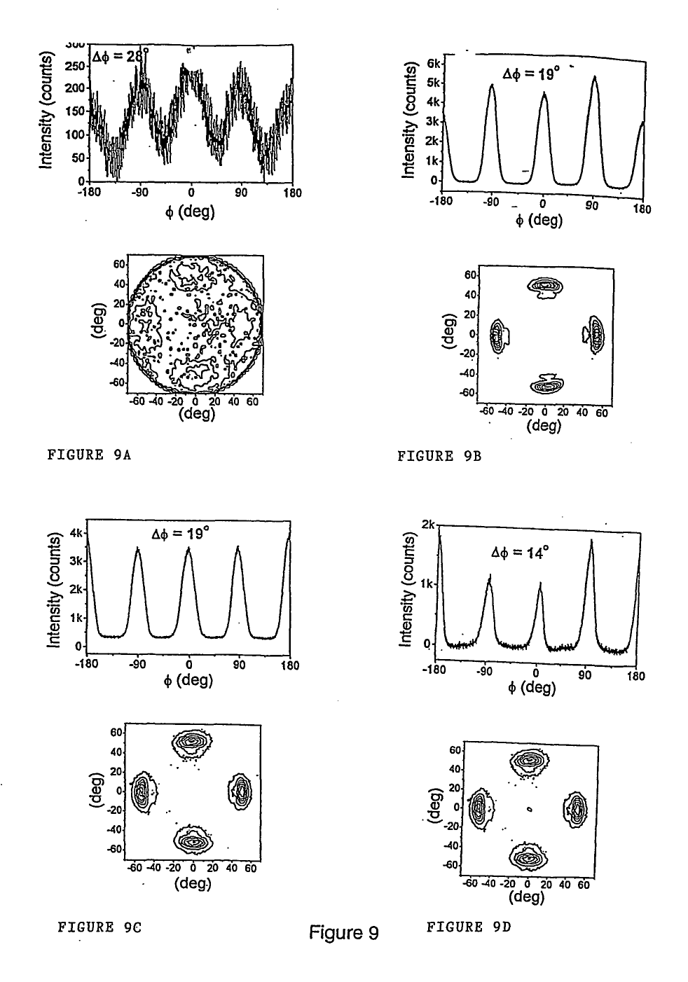

Biaxial YSZ buffer layers were deposited by the DIBAD method onto Hastelloy substrates as a function of ion beam energy. The films were bombarded during growth by Ar+ ions at angle of incidence θ=55° and energy in the range from 100 to 400 eV. FIG. 9 shows the YSZ(111) x-ray phi scans and pole figures, where FIG. 9a is for beam energy of 100 eV, FIG. 9b is for beam energy of 200 eV, FIG. 9c is for beam energy of 300 eV, and FIG. 9d is for beam energy 400 eV. The results demonstrate that a sharp texture is obtained at the higher energies.

### EXAMPLE 4

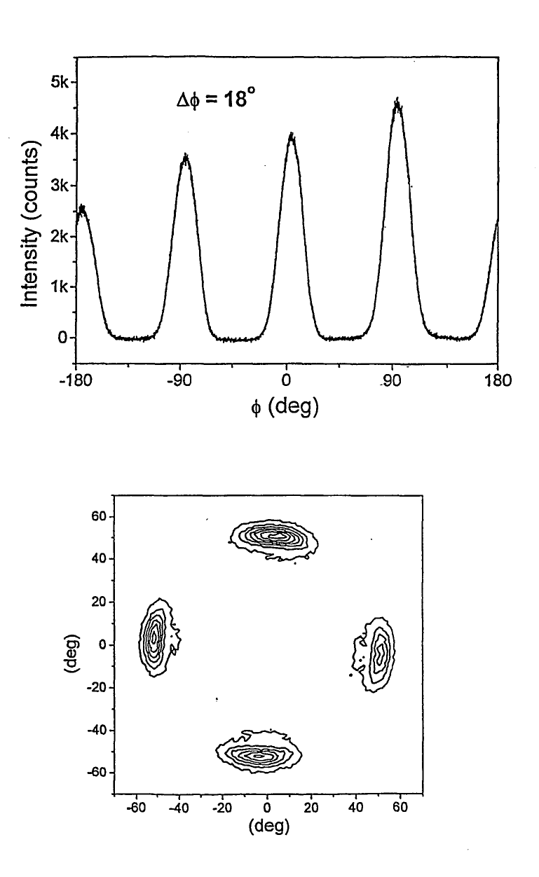

Biaxial YSZ buffer layers were deposited onto Hastelloy substrates by the sequential DIBAD method where each ion beam bombarded the film for periods of 10 to 60 minutes. FIG. 10 shows YSZ(111) x-ray phi scan and pole figures of a typical film 300 nm thick deposited for a total time of two hours where each ion beam bombarded the film for 30 minutes at a time. The other deposition conditions were: Ar+ ions; angle of incidence θ=55°; ion beam energy=200 eV; ion to atom arrival rate ratio=0.04.

### EXAMPLE 5

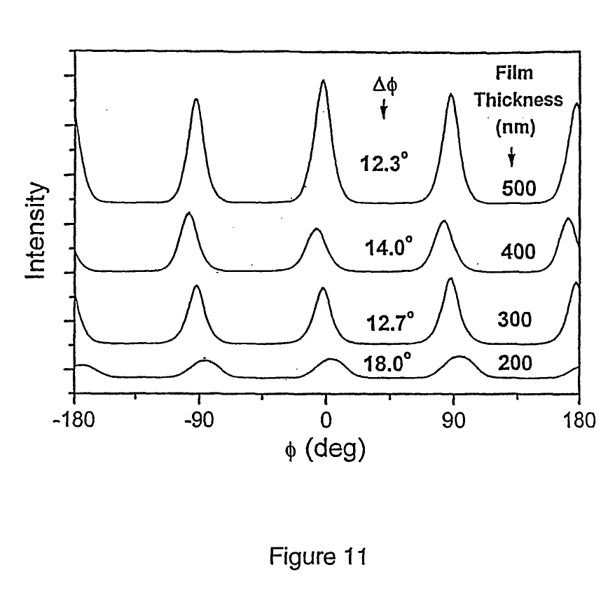

Four biaxial YSZ buffer layers varying in thickness were deposited onto Hastelloy substrates by the DIBAD method to investigate the evolution of texture with film thickness. The layers had thicknesses of 200, 300, 400 and 500 nm and were otherwise deposited under identical conditions: Ar+ ions; angle of incidence θ=55°; ion beam energy=400 eV; ion to atom arrival rate ratio=0.5. FIG. 11 shows plots of YSZ(111) x-ray phi scans. It is clear from these results that under the present deposition conditions the DIBAD method achieves a high degree of biaxial alignment, ie. Δφ=12°, for films about 300 nm thick. As the thickness increases from 200 to 300 nm there is a significant improvement in the degree of biaxial alignment so that films 300 nm or thicker have Δφ of about 12°. It is important to note that an acceptable sharp biaxial texture of Δφ=18° is obtained by DIBAD for 200 nm thick films compared to thicknesses greater than 500 nm reported by Freyhardt et al (IEEE Trans. Appl. Supercon. Vol.7 (1997), pp. 1426-31) and about 1000 nm reported by lijima et al (J. Mater. Res. Vol.13 (1998), pp. 3106-3113) when using the IBAD method. Also, Freyhardt et al reported achieving Δφ=12° when films exceeded 1500 nm thickness while in the present example Δφ=12° is achieved for 200-300 nm thick films.

### EXAMPLE 6

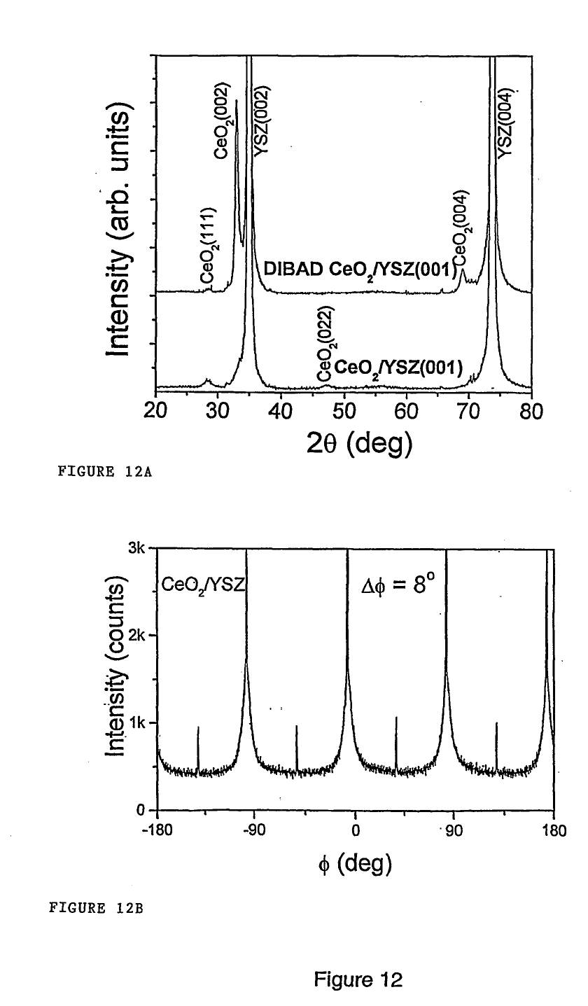

Some high-melting temperature oxides such as CeO₂ are very difficult to prepare at low temperatures as epitaxial thin films. Films of CeO₂ were deposited at room temperature onto single crystal YSZ(100) substrates using conventional magnetron sputtering without ion-beam assistance, and by DIBAD. FIG. 12a shows x-ray diffractions of two CeO₂ films. The film deposited without ion-beam assistance is randomly oriented while the one deposited by DIBAD is highly c-axis aligned and x-ray φ-scans shown in FIG. 12b show it to have a high degree of biaxial alignment with Δφ=8°. The very sharp peaks in FIG. 12b belong to the YSZ(100) substrate.

### EXAMPLE 7

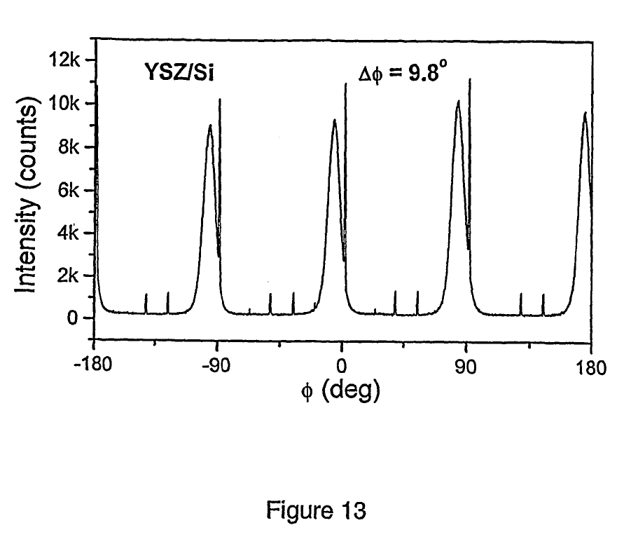

The DIBAD method was used to deposit YSZ buffer layers onto crystalline silicon substrates. FIG. 13 shows the YSZ(111) x-ray phi scan. A high degree of biaxial alignment is evident with Δφ=9.8°. The very sharp peaks belong to the Si(100) substrate.

Formation of Textured Superconducting Deposits and YBCO Tapes

### EXAMPLE 8

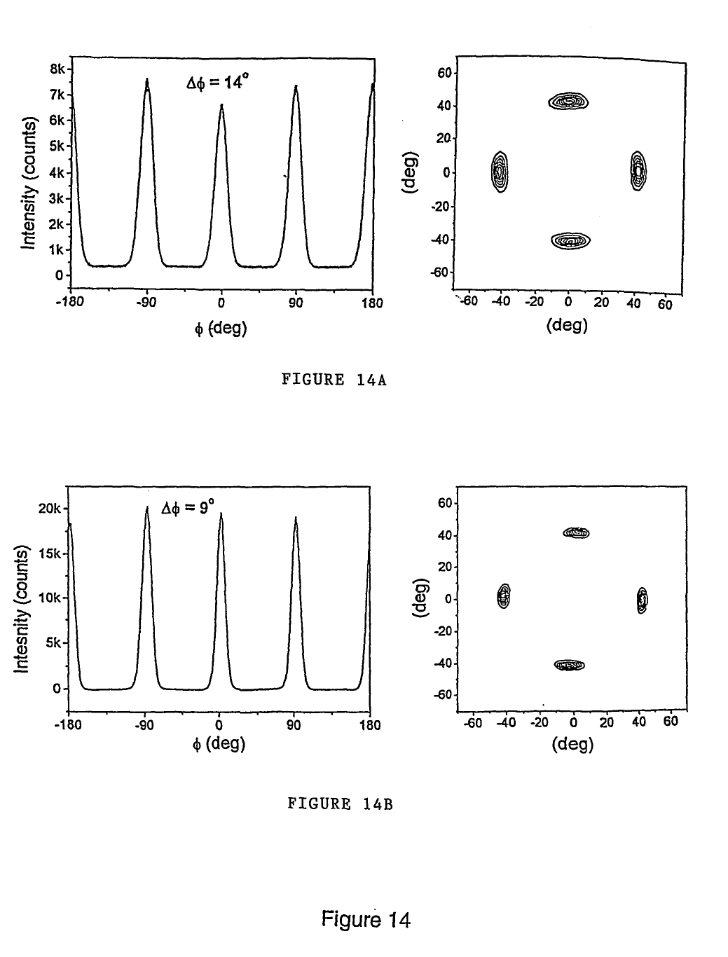

A biaxially textured YSZ buffer layer with YSZ(111) phi scan Δφ=19° was deposited onto a Hastelloy tape substrate by the DIBAD method according to Example 1. The substrate was then placed in a laboratory scale magnetron system [Sawides and Katsaros, Thin Solid Films, vol.228 (1993), pp. 182-185] and an epitaxial YBCO film (300 nm thick) was deposited upon it forming a superconducting tape. The YBCO(103) x-ray phi scan and pole figures of the YBCO/YSZ/Has tape revealed a highly textured superconducting deposit having YBCO (103) x-ray phi scan Δφ=14° as shown by FIG. 14(a) and a critical current density J_{c}(77K)=0.9×10⁶ A/cm². The process was repeated and optimised to produce another YSZ buffer layer onto a Hastelloy substrate with enhanced biaxial alignment, ie. YSZ(111)Δφ=14°. Deposition of YBCO onto the substrate yielded a YBCO tape with improved properties, ie. YBCO (103) x-ray phi scan Δφ=9° (as shown by FIG. 14(b)) and J_{c}(77K)=1.2×10⁶ A/cm².

### EXAMPLE 9

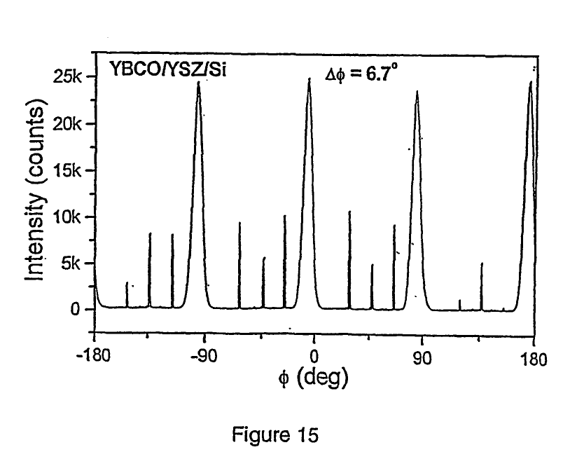

A buffered substrate (YSZ/Si), prepared as described by Example 7, was coated with a YBCO film to form a YBCO/YSZ/Si superconducting article. FIG. 15 shows the YBCO(103) x-ray phi scan. It can be seen that the YBCO film has enhanced texture with Δφ=6.7°.

### EXAMPLE 10

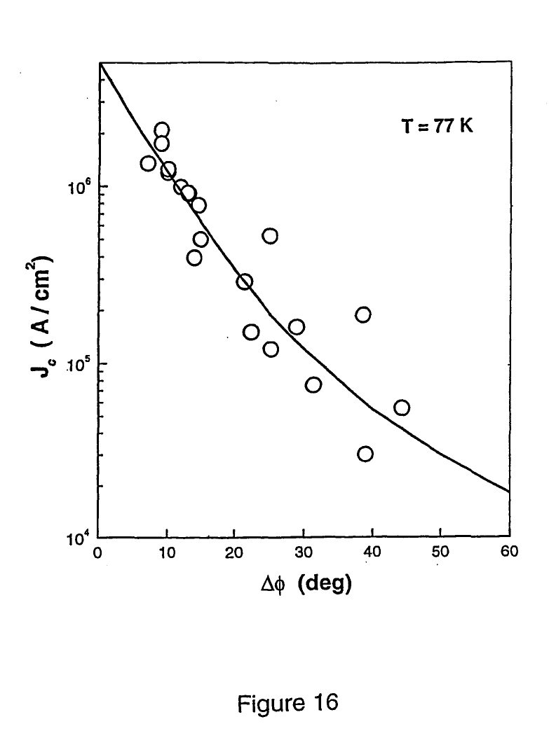

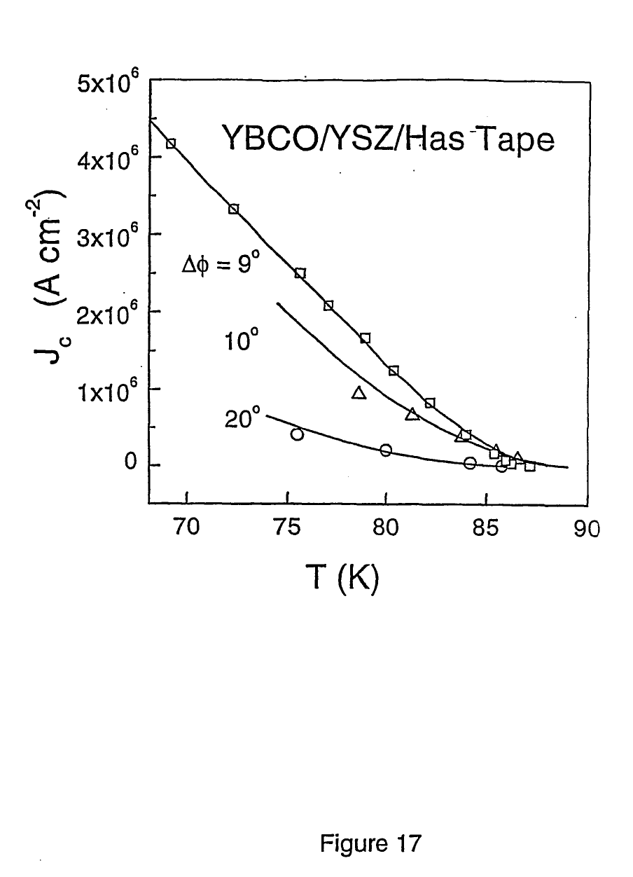

YSZ buffer layers were deposited by DIBAD onto Hastelloy substrates using different deposition conditions in order to obtain a wide range of texture. YBCO films were then deposited onto these substrates to establish the variation of J_{c} with Δφ. FIG. 16 is a plot of J_{c} versus the YBCO(103) x-ray phi scan Δφ showing the J_{c} measurements represented by circles and the general trend represented by the solid line. These measurements show clearly that J_{c} improves considerably as the degree of biaxial alignment of the YBCO films is improved (ie. as Δφ decreases). Commercial considerations indicate that YBCO tapes are required to have J_{c} greater than 5×10⁵ A/cm² and preferably greater than 10⁶ A/cm² for practical large scale power applications at liquid nitrogen temperatures (77 K). The results of Example 8 and FIG. 16 show that YBCO tapes with very high J_{c}(77K) (˜10⁶ A/cm²) can be fabricated using biaxially aligned YSZ buffer layers deposited by the DIBAD method of the present invention. Measurements of J_{c} as a function of temperature (FIG. 17) further demonstrate the enhancement of J_{c} with decreasing Δφ. At temperatures below about 80 K the J_{c} of YBCO tapes rises approximately linearly with decreasing temperature.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A method of depositing a film onto a surface of a substrate comprising he steps of:
providing the substrate in a controlled atmosphere;
exposing the substrate to a vapour comprising a film-forming species; and
while the substrate is exposed to the vapour, providing at least first and second ion beams incident towards the surface of the substrate to assist formation of the film, wherein an axis of incidence of the first ion beam relative to the surface of the substrate is distinct from an axis of incidence of the second ion beam relative to the surface of the substrate.

2. The method of claim 1 wherein the axis of incidence of the first ion beam and the axis of incidence of the second ion beam are symmetrically disposed about the normal of the surface of the substrate.

3. The method of claim 1 or claim 2 wherein the first and second ion beams are incident at an angle in the range of substantially 50-60 degrees from the normal of the surface of the substrate.

4. The method of claim 3 wherein the first and second ion beams are incident at an angle of substantially 55 degrees from the normal of the surface of the substrate.

5. The method of any preceding claim wherein the first and second ion beams comprise ions of a noble gas.

6. The method of claim 5 wherein the first and second ion beams comprise Ar ions.

7. The method of claim 5 wherein the first and second ion beam comprise Kr ions.

8. The method of claim 5 wherein the first and second ion beams comprise Xe ions.

9. The method of any preceding claim wherein the step of providing first and second ion beams comprises simultaneously providing the first and second ion beams.

10. The method of any one of claims 1 to 8 wherein the step of providing the first and second ion beams comprises sequentially providing the first and second ion beams.

11. The method of any preceding claim further comprising the step of providing a third ion beam.

12. The method of claim 11 wherein the axes of incidence of the first second and third ion beams are symmetrically disposed at 120 degree intervals about a normal of the surface of the substrate.

13. The method of claim 11 or claim 12, and further comprising the step of providing a fourth ion beam.

14. The method of claim 13 wherein the axes of incidence of the first, second, third and fourth ion beams are situated at 90 degree intervals about a normal of the surface of the substrate.

15. The method of any preceding claim and further comprising the step of forming a superconducting article by depositing an epitaxial superconducting material over the film.

16. The method of claim 15 wherein the superconducting material is deposited by magnetron deposition.

17. The method of claim 15 wherein the superconducting material is deposited by laser ablation.

18. The method of claim 15 wherein the superconducting material is deposited by chemical vapour deposition.

19. The method of any one of claims 15 to 18 wherein the superconducting material is formed with an x-ray phi scan peak of not more than 20 degrees FWHM.

20. The method of any one of claims 15 to 19 and further comprising the step of forming a capping layer over the epitaxial superconducting material.

21. The method of any preceding claim and further comprising the step of negatively electrically biasing the substrate during formation of the film.

22. The method of any preceding claim wherein the substrate comprises a crystalline substrate.

23. The method of any one of claims 1 to 21 wherein the substrate comprises an amorphous substrate.

24. The method of any preceding claim wherein the film comprises a buffer layer.

25. The method of claim 22 wherein the crystalline substrate is a single crystal substrate.

26. The method of claim 22 wherein the crystalline substrate is a metallic substrate.

27. The method of claim 22 wherein the crystalline substrate is an alloy substrate.

28. The method of claim 22 wherein the crystalline substrate is a semiconductor substrate

29. The method of claim 22 wherein the substrate is a ceramic substrate.

30. The method of claim 29 wherein the ceramic substrate comprises a yttria stabilised zirconia substrate.

31. The method of any one of claims 1 to 30, further comprising the step of controlling a ratio between ion bombardment and film forming species, the arrival rate ratio, in order to optimise biaxial texture and deposition rate.

32. The method of claim 31 wherein the ion to film forming species ratio is between substantially 0.02 and substantially 0.5.

33. The method of claim 32 wherein the ion to film forming species ratio is between substantially 0.04 and substantially 0.05.

34. The method of any one of claims 1 to 33 wherein the ion beam energy is between substantially 100 eV and substantially 400 eV.

35. The method of any one of claims 1 to 34 wherein the film forming species comprises atoms or molecules capable of forming as a thin film crystalline material.

36. The method of claim 35 wherein the film forming species is an oxide.

37. The method of claim 36 wherein the film forming species is CeO₂.

38. The method of any one of claims 35 to 37 wherein the film forming species comprises atoms or molecules capable of forming as a thin film crystalline material having a cubic structure.

39. The method of claim 38 wherein the film forming species is MgO.

40. The method of claim 38 wherein the film forming species is yttria stabilised zirconia.

41. The method of any one of claims 35 to 37 wherein the film forming species comprises atoms or molecules capable of forming as a thin film crystalline material having a perovskite-related structure.

42. The method of any one of claims 1 to 35 wherein the film forming species comprises a metal.

43. The method of claim 42 wherein the film forming species comprises silver.

44. The method of claim 42 wherein the film forming species comprises niobium.

45. The method of any one of claims 1 to 44 wherein the film comprises a buffer layer, and wherein the method further comprises the step of forming a superconducting layer over the buffer layer.

46. An apparatus for depositing a film onto a surface of a substrate, the apparatus comprising:
a chamber to control the atmosphere in which the substrate is situated;
a vapour source to provide a vapour comprising a film forming species to the surface of the substrate; and
at least first and second ion beam sources operable to provide at least first and second ion beams incident towards the surface of the substrate to assist formation of the film, wherein an axis of incidence of the first ion beam relative to the surface of the substrate is distinct from an axis of incidence of the second ion beam relative to the surface of the substrate.

47. The apparatus as claimed in claim 46 wherein the ion beam sources are operable to provide ion beams sequentially.

48. The apparatus as claimed in claim 46 or claim 47 wherein the ion beam sources are operable to provide ion beams simultaneously.

49. The apparatus as claimed in any one of claims 46 to 48 wherein the first and second ion beam sources are Kaufman ion guns capable of providing a collimated source of energetic ions.

50. The apparatus as claimed in any one of claims 46 to 49, further comprising at least one shutter for selectively obstructing at least one of said ion beams.

51. The apparatus as claimed in any one of claims 46 to 50 wherein the vapour source providing the film forming species comprises a magnetron sputter source capable of providing a physical vapour of atoms or molecules.

52. The apparatus as claimed in any one of claims 46 to 51, further comprising means to apply a negative bias to the substrate.

53. The apparatus as claimed in any one of claims 46 to 52, further comprising means for passing an elongate substrate past the first and second ion beam sources for deposition of the film along the substrate.

54. The apparatus as claimed in claim 53 wherein the means for passing the elongate substrate are adapted to simultaneously pass a plurality of elongate substrates past the first and second ion beam sources for simultaneous formation of a film along each of said elongate substrates.

55. The apparatus as claimed in any one of claims 46 to 54 wherein the substrate is a sheet.

56. The apparatus as claimed in any one of claims 46 to 54 wherein the substrate is a disc.

57. The apparatus as claimed in any one of claims 46 to 54 wherein the substrate is a wire rod.

58. The apparatus as claimed in any one of claims 46 to 54 wherein the substrate is a tube.

59. The apparatus as claimed in any one of claims 46 to 54 wherein the substrate is a tape.

60. The apparatus as claimed in any one of claims 46 to 54 wherein the deposited film is a c-axis oriented, biaxially textured perovskite-like electro-ceramic film.

61. A sharply biaxially aligned film formed over a substrate in accordance with the method of any one of claims 1 to 45.

62. The film of claim 61 wherein the film has a biaxial alignment of Δφ<18°, and has a thickness of substantially 200 nm or less.

63. The film of claim 61 wherein the film has a biaxial alignment of Δφ<12°, and has a thickness of substantially 300 nm or less.
